(19) United States
(12) Patent Application Publication
(10) Pub. No.: US 2003/0099007 A1
(43) Pub. Date: May 29, 2003

(54) Selectable gloss levels and placement

(76) Inventors: David K. Towner, Boise, ID (US); Ben B. Tyson, Eagle, ID (US); Laurent A. Regimbal, Round Rock, TX (US); Lori Clifton, Boise, ID (US)

Correspondence Address: HEWLETT-PACKARD COMPANY, Intellectual Property Administration, P.O. Box 272400, Fort Collins, CO, 80527-2400, US

(21) Appl. No.: 09/995,776

(22) Filed: Nov. 29, 2001

(51) Int. Cl. G03F 3/08

(52) U.S. Cl. 358/520

(57) ABSTRACT

A method of varying gloss in hard copy output from a hard copy output engine includes providing a user with a user-adjustable control for varying hard copy output gloss and varying at least one processing parameter in producing the hard copy output in response to user adjustment of the user-adjustable control to provide a first user-selected gloss level over a first portion of a page of hard copy output.

### FIELD OF THE INVENTION

The invention relates to printers and other hard copy output engines. More particularly, the invention relates to user selectable gloss levels and user selectable placement of gloss areas within a page produced by a hard copy output engine.

### BACKGROUND OF THE INVENTION

As computer systems and data communications systems have developed, the variety and number of types of hard copy output available from such systems has increased. Concurrently, the needs and expectations of printer users have also increased. Text documents, business graphics and continuous tone images, for example, may require different treatment by a hard copy output engine in order to best serve their intended purposes. To some extent, the needs and expectations of printer users may be met by use of different types of hard copy media, or by use of different types of hard copy output engines.

However, it is extremely helpful to be able to produce different types of hard copy output from a given hard copy output engine. This may reduce the number of different hard copy output engines a user requires and may simplify routing of hard copy jobs, pickup and distribution of hard copy output and also ordering and maintenance of stocks of consumable supplies such as toner or other pigmentation agents and other types of consumables.

Additionally, it is helpful to be able to process multiple types of hard copy output using as few types of hard copy media as possible. This tends to simplify production of hard copy products, such as reports or other documents, and also simplifies the tasks involved in ordering and maintaining supplies of hard copy media. One of the variables associated with hard copy output, and with the choice of hard copy media, is gloss.

Gloss is a measure of the reflective properties of a surface. High gloss indicates that the surface reflections are mirror-like or specular, where the angle of reflection closely matches the angle of incidence of light illuminating the surface. Low gloss indicates that the surface produces diffuse reflections where incident light is scattered over a broad range of angles during reflection. High gloss allows a viewer to tilt the image surface as necessary to direct specular reflections of ambient light sources away from the viewer's eyes. This allows the viewer to see relatively pure colors of the image with minimal white light from scattered surface reflections. High gloss, with its attendant increase in contrast and color gamut can also make some images more intelligible to the viewer by obviating veiling glare from scattered light

Low gloss may eliminate the annoyance of having to orient the hard copy output with respect to the viewer and ambient light sources to reduce glare effects by distributing the reflected light over a broad range of angles. Also, fingerprints and other forms of surface contamination are generally less visible on low gloss hard copy output. However, a low gloss image may not allow the viewer to entirely eliminate specular surface reflections from ambient light sources and generally adds an amount of ambient light to every color in the image. As a result, purity of perceived colors may be reduced, limiting the contrast and color gamut available for low gloss images. Despite these limitations, many users prefer low gloss hard copy output for certain purposes, often including black and white text documents.

Scattering of light from hard copy output may be from the surface or from within pigmentation layers, such as toner layers, forming the image. While surface scattering often dominates the visual perception of gloss, scattering from within image-forming layers also affects perceived gloss. Highest perceived gloss is attained when surface scattering is minimized (as from a very smooth surface) and when scattering within image-forming layers is also minimized. Lowest perceived gloss is attained when surface scattering and scattering within image-forming layers are both high. Thus, the perception of gloss can be adjusted by controlling surface scattering, by controlling scattering within image-forming layers, or a combination of the two.

Exemplary techniques for gloss adjustment, some of which are intended to overcome variations in gloss due to non-uniformities in generation of hard copy output, are described, for example, in “Reproduction Apparatus Providing Selectable Image Quality And Gloss”, issued to Aslam et al., U.S. Pat. No. 5,887,234; and “Method For Applying Uniform Gloss Over The Entire Print”, issued to Dalal, U.S. Pat. No. 6,167,224, which patents are hereby incorporated herein by reference for their teachings relevant to gloss from, and construction and operation of, hard copy output engines.

Other exemplary techniques are described in “Method And Apparatus For Forming High Gloss Toner Images Using Low Gloss Toner Formulation”, issued to Boyd et al. and assigned to the assignee of the instant application, U.S. Pat. No. 5,852,462; “Method And Apparatus For Developing Color Images Using Dry Toners And An Intermediate Transfer Member”, issued to Camis and assigned to the assignee of the instant application, U.S. Pat. No. 5,314,774; and “Control Panel For An Image Forming Device”, issued to Okamura and assigned to the assignee of the instant application, U.S. Pat. No. 6,070,988, which patents are hereby incorporated herein by reference for their teachings relevant to gloss from, and construction and operation of, hard copy output engines.

As a result of the various effects of gloss on perceived image quality and achievable color gamut, users may need to stock more types of hard copy media than is desirable, and may not achieve their gloss goals for a given document regardless of media availability. What is needed is a way to facilitate generation of high quality, hard copy output with a broad range of gloss treatments from readily available hard copy media using hard copy output engines.

### SUMMARY OF THE INVENTION

In accordance with an aspect of the present invention, a method of varying gloss in hard copy output from a hard copy output engine includes providing a user with a user-adjustable control for varying hard copy output gloss and varying at least one processing parameter in producing the hard copy output in response to user adjustment of the user-adjustable control to provide a first user-selected gloss level over a first portion of a page of hard copy output.

In accordance with another aspect of the present invention, an apparatus for varying gloss in hard copy output from a hard copy output engine includes a user interface facilitating user-adjustable variation of hard copy output gloss and a control mechanism configured to vary at least one processing parameter in producing the hard copy output in response to user adjustment of the user-adjustable control to provide a first user-selected gloss level over a first portion of a page of hard copy output.

In accordance with yet another aspect of the present invention, a computer implemented control system for a hard copy output engine includes processing circuitry coupled to the hard copy output engine. The processing circuitry is configured to provide a user interface facilitating user-adjustable variation of hard copy output gloss and to vary at least one processing parameter in producing the hard copy output in response to user adjustment of the user-adjustable control to provide a first user-selected gloss level over a first portion of a page of hard copy output.

Other features and advantages of the invention will become apparent to those of ordinary skill in the art upon review of the following detailed description, claims and drawings.

### DESCRIPTION OF THE DRAWINGS

FIG. 1 is a simplified block diagram of a computer network including a computer and a hard copy output engine, in accordance with an embodiment of the present invention.

FIG. 2 illustrates an exemplary laser printer as an example of the hard copy output engine of FIG. 1, in accordance with an embodiment of the present invention.

FIG. 3 is a simplified flowchart illustrating a process for applying user-selectable gloss levels to hard copy output from the laser printer of FIG. 2, in accordance with an embodiment of the present invention.

### DETAILED DESCRIPTION OF THE INVENTION

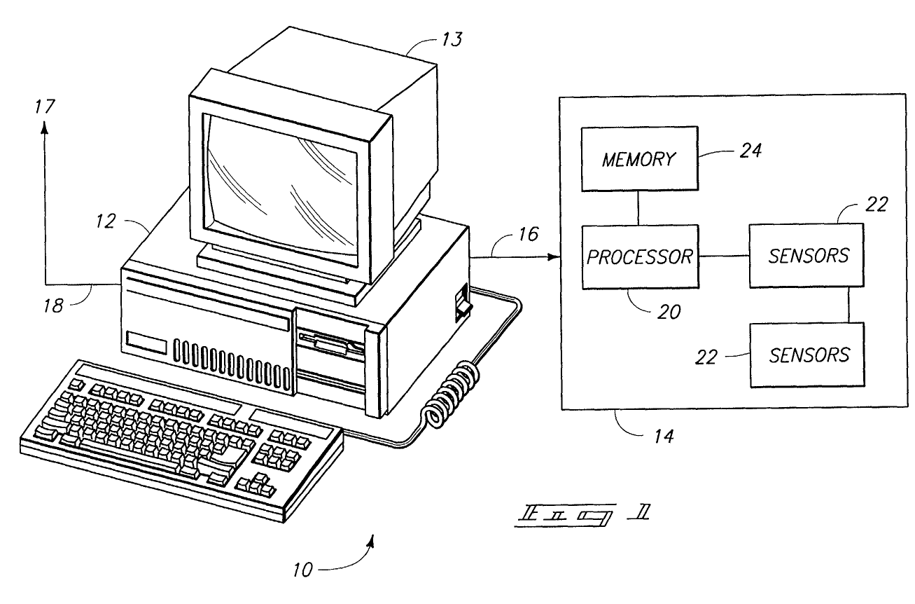

FIG. 1 is a simplified block diagram of a computer network 10 including a computer 12 having a monitor 13. The system also includes a hard copy output engine 14, in accordance with an embodiment of the present invention. The 15 computer 12 is coupled to the hard copy output engine 14 via a bus 16 allowing either the computer 12 or the hard copy output engine 14 to initiate data communications with the other. In one embodiment, the hard copy output engine 14 is a device such as a printer, copier, facsimile machine, or a multifunction device capable of providing two or more such functions. In one embodiment, the system 10 is coupled to an external interconnection 17 via a data path 18.

In one embodiment, the data path 18 includes an intranet. In one embodiment, the data path 18 includes a local area network (LAN) or wide area network (WAN). In one embodiment, the data path 18 includes Internet access. In one embodiment, the computer 12 and the hard copy output engine 14 are capable of exchanging data via a protocol compatible with potential presence of other computers 12 or hard copy output engines 14 on the bus 16. In one embodiment, the computer 12 and the hard copy output engine 14 employ an object-oriented request-reply protocol supporting asynchronous printer query, control and monitor capabilities, and that is capable of documenting the requests, replies and data types supported by the protocol. The hard copy output engine 14 includes a controller 20, such as a conventional microprocessor or microcontroller.

In many cases, the user may have a preference for a relatively high level of gloss in the hard copy output from the hard copy output engine 14. These users may equate high gloss levels with high quality hard copy output. Other users dislike glossy images, finding them difficult to view due to the need to tilt the hard copy output to eliminate specular reflections from overhead lights. Many users have gloss level preferences that depend on the intended purpose or content of the hard copy output product. As a result, it is desirable for the user to be able to select a desired gloss level, for example, via a print properties dialog box shown on the monitor 13 using a tactile input device such as a mouse (not illustrated) or keyboard, and it is also desirable to be able to achieve different gloss levels for a given type of hard copy media, such as paper.

Studies indicate that preferred gloss values for common hard copy applications are approximately 30 gloss units (GU, for example as measured with a micro gloss 75 degree BYK Gardner gloss meter, available from BYK Gardner USA, 2435 Linden Lane, Silver Springs, Md. 20910) for black and white text; 40 GU for business graphics; and 55 to 75 GU for continuous tone images, such as photographs. These data suggest that nearly all users would be satisfied by the ability to adjust gloss values over a suitable 45 GU range.

For some types of hard copy output engines, the gloss level of printed areas tends to adopt the gloss level of the underlying hard copy media. In these cases, users typically select hard copy media having the gloss level they prefer for printed and unprinted areas. For other types of hard copy output engines, the gloss level of printed areas tends to mask the gloss level of the underlying hard copy media. This is commonly the case, for example, with electrophotographic hard copy output devices such as laser printers which form images using pigmented toner. In these cases, toner gloss may be dynamically adjustable during generation of hard copy output by controlling one or more process parameters, as is described in more detail below. This may be usefully employed to create opportunity to deliver gloss levels matching individual user preferences, or requirements for particular hard copy products.

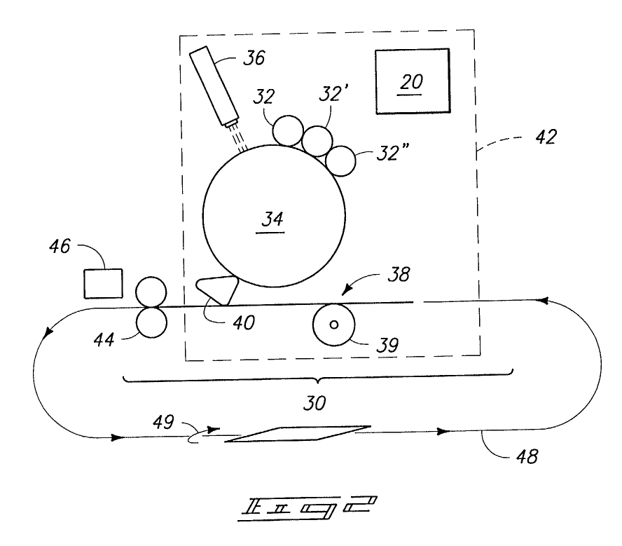

FIG. 2 illustrates an exemplary laser printer 30 as an example of the hard copy output engine 14 of FIG. 1, in accordance with an embodiment of the present invention. Some hard copy output engines 14, generally known as “laser printers” 30, employ toner supplied by toner cartridges 32. The toner is selectively developed onto a photoconductor 34 via interaction with a laser 36 and is then applied to a hard copy medium 38. The hard copy medium 38, the photoconductor 34 and other moving parts are collectively powered by a mechanical power source or sources represented in FIG. 2 by a drive motor 39. In one embodiment, an intermediate transfer belt 40 transfers toner from the photoconductor 34 to the hard copy medium 38.

The controller 20 coordinates interaction of components forming the laser printer 30. The toner cartridges 32, photoconductor 34, laser 36, intermediate transfer belt 40 and drive mechanisms 39 therefore collectively comprise a laser printer sub-assembly 42 that transfers dry pigmentation patterns to the hard copy medium 38.

In one embodiment, the hard copy medium 38 acquires the toner directly from the photoconductor 34. In one embodiment, a plurality of laser printer sub-assemblies 42 may each provide a portion of the total pattern to be printed on the hard copy medium 38. In one embodiment, different toner cartridges 32, 32′, 32″ are employed to provide image portions each using a toner having different gloss or pigmentation properties.

The toner is then fused to the hard copy medium 38 via a heated roller, or fuser 44. In one embodiment, a sensor 46 that is also coupled to the controller 20 assesses gloss on the hard copy medium 38 after the fusing process.

In laser printers such as the laser printer 30, the achieved gloss level may be determined by factors including: fuser 44 temperature; fuser 44 pressure; fusing time (which is determined by nip width and paper speed); toner mass per unit area; fuser 44 roller nip geometry; and toner formulation, among other things. Of these, at least fuser 44 temperature, fuser 44 pressure and fusing time may be dynamically adjusted to provide a user page-to-page or job-to-job control of gloss level.

Fusing a toner image ordinarily involves softening or melting particles of toner, often a pigmented thermoplastic polymer under pressure in the a space between two rollers forming the fuser 44. The fusing process is gradational, ranging from sintering of toner particles at mutual points of contact with little wetting of the underlying hard copy medium 38, to full melting of toner particles, which may be accompanied by wetting of the hard copy medium 38 and/or wicking of melted toner into pores in the hard copy medium 38.

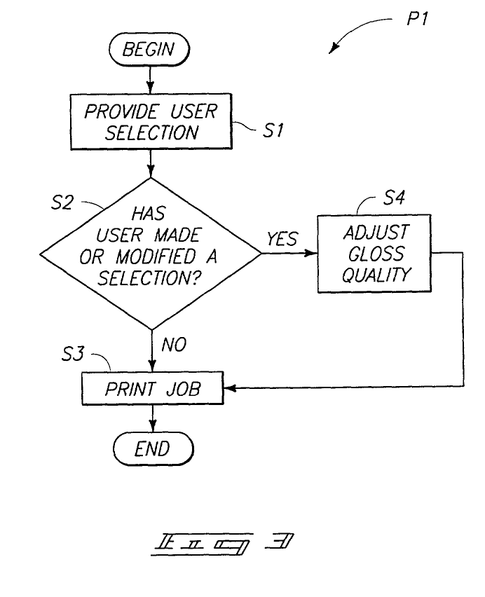

FIG. 3 is a simplified flowchart illustrating a process P1 for applying user-selectable gloss levels to hard copy output from the laser printer 30 of FIG. 2, in accordance with an embodiment of the present invention. The process P1 begins by providing user selections from a menu of possible selections in a step S1 .

In one embodiment, the user selections may be offered via an interactive panel on the hard copy output engine 14 of FIG. 1. In one embodiment, the user selections may be offered via a conventional graphical user interface associated with the computer 12.

In a query task S2, the process P1 determines when the user has made a gloss property selection or has modified a gloss property selection.

When the query task S2 determines that the user has not made or modified a gloss property selection, the process P1 passes control to a step S3.

When the query task S2 determines that the user has made a gloss property selection or has modified a gloss property selection, control passes to a step S4.

In the step S4, the process P1 adjusts one or more print parameters to influence the gloss properties of the hard copy medium 38. Control then passes to the step S3.

In the step S3, the process P1 prints hard copy output using one or more modified print parameters to provide the desired gloss properties.

The process P1 then ends.

The process P1 adjusts one or more print parameters in accordance with a gloss control method. The range of print parameters that the process P1 adjusts may include print parameters for an individual page or for portions of a page, as determined by the gloss control method. An example of the latter is to apply a gloss modification agent that modifies gloss properties only, to one or more selected portions of a page.

The gloss control methods and print parameters that may be adjusted by the process P1 in accordance with these methods are discussed in more detail below.

Unfused toner has very low gloss, which increases progressively as strongly light-scattering toner particles fuse and flow to create a low porosity layer having a smooth surface. As a result, gloss control may be offered via:

(1) Passive Gloss Matching Method. This method relies on choosing the chemistry and physics of special toner formulations to adopt the gloss of the hard copy medium 38. No dynamic user input or engine response is involved, and the user controls gloss via selection of appropriate hard copy media.

(2) Active Gloss Matching Method. This method relies on sensing of the gloss level of the hard copy medium 38, followed by adjustment of the printing process to deliver images gloss matching the gloss level of the medium 38. This method may provide greater control to the hard copy output engine firmware and software, and may provide limited control to the user as well.

(3) User Selectable Gloss Control Method. User-settable gloss levels for a print job, for individual pages within a print job, or for user selected areas within a specified page, may provide greater user control of gloss within a specific hard copy output product.

(4) Hybrid Gloss Control Method. Including Active Gloss Matching as a default setting but permitting user override via User Selectable Gloss Control may provide greater user control together with greater user satisfaction by requiring user input only for specific, user-chosen elements of a hard copy output product.

(5) Closed Loop Gloss Control Method. Output gloss sensor 46 is included in the hard copy output engine 30 to measure an achieved gloss level on hard copy output. The achieved gloss level is compared with a user-defined target gloss level to produce a gloss error signal. A gloss control servo loop dynamically adjusts one or more print parameters in response to the gloss error signal, thereby reducing the gloss error and increasing gloss uniformity in hard copy output. Closed Loop Gloss Control is useful, for example, when a number of similar hard copy products are desired, and when gloss levels might otherwise vary as different components within the hard copy output engine 30 change temperature or as other parameters vary, or as various consumable items (e.g., toner, gloss or pigmentation agents) are consumed. Additionally, Closed Loop Gloss Control may be combined with other methods to provide enhanced convenience and hard copy output control or uniformity.

In hard copy output engines 30 that rely on fusing of toner agents, gloss control may be implemented by controlling a variety of print parameters. These parameters may include:

(1) Toner Mass Density (e.g., toner mass per unit area of hard copy medium 38). The amount of toner provided to the photoconductive drum 34 and thus transferred to the medium 38 strongly affects achieved gloss. The toner mass density may be modified by the controller 20 in response to user input. This allows multiple user-selectable gloss levels within a page, as well as page-to-page user-chosen variations in gloss. Using this parameter to control gloss is best suited to images having only solid printed areas. Images with halftone areas may show unwanted changes in halftone density.

(2) Media Gloss. Passive Gloss Matching makes use of toner formulations and fusing processes which increase the ability of fused toner to adopt the gloss level of the underlying hard copy medium 38, thereby providing a range of output gloss levels and allowing many users to be satisfied. The user selects the hard copy output medium to determine a gloss level. Examples of toner enhancements which enable Passive Gloss Matching include toner having a reduced viscosity during fusing and toner having a reduced surface tension during fusing. These enhancements increase wetting of the output medium and absorption of toner into the matrix or pore spaces within the output medium. Less toner thereby remains on the surface of the medium, allowing the toner layer to conform more closely to the surface of the output medium and enabling toner gloss to better match the gloss of the output medium. Another example is toner having a carrier material which volatilizes during fusing, minimizing the deposition of a film-forming layer on the surface of the output medium after fusing. In these examples, smoother hard copy media and media with reduced pore volume will produce glossier output pages. In contrast, many current toner formulations strongly mask the gloss of the underlying hard copy medium 38 by forming a thick layer that rests on the surface of the medium.

(3) Fusing Temperature. Fusing temperature strongly affects toner gloss, with higher fusing temperature generally producing higher gloss. Inductively heated fusers 44 provide fusing temperature control with sufficiently high temporal bandwidth and therefore sufficiently rapid response times to allow page-to-page gloss adjustment with minimal impact on hard copy output engine 30 performance.

The fuser 44 temperature may be controlled by the controller 20 using conventional methods in response to user input. Job-to-job gloss changes result in even less impact on hard copy output engine 30 performance. In general, increasing fuser 44 temperature results in increased gloss levels.

(4) Fusing Pressure. Fusing pressure has significant influence on achieved toner gloss levels. The nip pressure in the fuser 44 (i.e., between the fuser roller and the backup roller) may be dynamically adjustable under electronic control using a variety of conventional actuation methods. This nip pressure may be controlled by the controller 20 using conventional methods in response to user input. In general, increasing nip pressure results in increased gloss levels. Varying this print parameter allows page-to-page gloss adjustment without impacting hard copy output engine 30 performance.

(5) Fusing Time. Adjustment of the speed with which hard copy media 38 passes through the fuser 44 (e.g., by varying speed of the drive mechanism 39 via the controller 20) significantly affects gloss levels in the completed hard copy output 38 product. The fusing time may be controlled by the controller 20 using conventional methods in response to user input.

Media speed adjustment during fusing is an independent print parameter for affecting achieved gloss levels in response to user inputs. Reduced paper speed increases fusing time and generally corresponds to increased achieved gloss levels at some cost in throughput. This parameter allows page-to-page gloss adjustment with some impact on hard copy output engine 30 performance.

(6) Fusing Temperature, Pressure And Time. By having the controller 20 vary any two or all three of these variables in combination in response to user input, numerous benefits are possible. These include:

(i) greater range over which gloss level may be varied;

(ii) reduction of gloss variability due to environmental variables, hard copy medium 38 weight, moisture content and the like;

(iii) reduced range of parameter variation for any one of these three variables; and

(iv) reduction of gloss level variation between different toners (e.g., different colors or different toner qualities).

(v) increase in fusing temperature without an increase in the temperature or heat output of the fuser itself. Fusing temperature is generally dependent on fusing time and fuser temperature. For example, a constant fuser heat output applied over a longer fusing time results in a higher achieved fusing temperature within the toner layer.

This combined print parameter also allows page-to-page gloss adjustment with minimal impact on hard copy output engine 30 performance.

(7) Cooling Rate. The rate at which a toner layer and underlying hard copy medium 38 cools following fusing affects achieved gloss levels, due to the effects of surface tension and reduced toner viscosity after the hard copy medium 38 is separated from the fuser 44. The cooling rate may be controlled by the controller 30 in response to user input, for example by modifying feed rates, adjusting fuser nip geometry as described in (8) below, raising or lowering air temperature or air flow rates on the output side of the fuser nip, or by using auxiliary post-fusing heating or cooling as described in (9) below. This print parameter also allows page-to-page gloss adjustment with minimal impact on hard copy output engine 30 performance.

(8) Nip Geometry. Adjustment of fuser nip geometry determines the geometry of separation of the hard copy medium 38 from the fuser 44, and thus affects cooling rate and micro-texture of the toner surface, both of which affect achieved gloss levels. Adjustments associated with nip geometry include:

(i) nip width,

(ii) distance beyond the nip that hard copy media remains in contact with the fuser roller, and

(iii) distance beyond the nip that hard copy media remains in contact with the fuser backup roller.

(9) Auxiliary Heating Or Cooling. Conventional systems employ the fuser 44 roller to supply the fusing heat. Auxiliary heat sources allow additional thermal bias to control pre-fusing media temperature, fusing temperature and/or post-fusing cooling rate. Auxiliary cooling devices allow selective removal of heat to adjust pre-fusing media temperature, fusing temperature and/or post-fusing cooling rate. For example:

(i) Heat applied prior to the input side of the fuser 44 allows fusing temperature to be influenced without changing fuser 44 heating parameters. The hard copy medium 38 may have contact with the intermediate transfer belt 40, which may include temperature control.

(ii) Toner layer temperature history may be affected by heating the backup roller of the fuser 44 or by including auxiliary heat sources within the fuser roller.

(iii) Post-fusing heating or cooling may be employed after fusing to affect either peak fusing temperature, fusing time at temperature or cooling rate, all of which influence achieved gloss levels as discussed above.

Post-heating or cooling may be accomplished, for example, using a second fuser roller with independently controllable temperature that is located in the paper path downstream from a first fuser roller. By maintaining the second fuser roller at a reduced temperature, by passive cooling, by active cooling using a Peltier effect device or by other means, the time toner is kept at elevated temperature may be reduced, generally reducing gloss. By maintaining the second fuser roller at an elevated temperature, by resistive or radiative heating for example, the time the toner is kept at elevated temperature may be extended, generally increasing gloss.

Ultrasonic, microwave and/or optical heating (employing any, several of or varying combinations of broad band, single frequency or multiple discrete frequencies) may be used in conjunction with any of these heat sources or may substitute for one or more conventional heat sources. These parameters may also be controlled by the controller 30 in response to user input. This method also allows page-to-page gloss adjustment with minimal impact on hard copy output engine 30 performance.

(10) Textured Rollers. Where a first and a second fuser roller are used, the surface texture of the two fuser rollers may be different. If, for example, the first fuser roller has a matte finish and the second fuser roller has a gloss finish, the gloss level of the printed pages may be continuously adjusted between low and high gloss by independently controlling the temperatures of the first and second rollers. In this example, the second roller may be heated to an elevated temperature to provide a higher gloss finish or it may be maintained at a lower temperature to provide a lower gloss finish.

(11) Multiple Pass Fusing. Passing the hard copy medium 38 through the fuser 44 more than once, for example via a duplex paper path 48, provides additional process flexibility and thus additional achieved toner gloss control range.

Duplex paper paths 48 typically also invert the hard copy medium 38, as represented by the arrow 49, to expose another surface of the hard copy medium 38 to toner, inks, gloss control agents etc. However, the controller 20 may provide an inverting or a non-inverting duplex path 48 or no duplex path in response to user input. This method allows page-to-page gloss adjustment.

(12) Multi-Gloss Toner. Optimization of toner formulation permits a wider range of achieved gloss levels in response to predetermined variations in one or more process parameters that affect achieved toner gloss levels. Toner formulated to controllably provide an increased range of gloss variation in response to incremental changes in process parameters is referred to herein as “multi-gloss toner”. Multi-gloss toner can be formulated, for example, to provide an increased range of achieved gloss level in response to predetermined changes in fusing time, temperature and pressure applied to the hard copy medium during fusing. Multi-gloss toner enables a hard copy output engine to produce hard copy output products having a wider range of gloss levels in response to predetermined changes in the one or more process parameters as directed by controller 20 in response to user input.

(13) Special Hard Copy Media Or Media Treatments. The hard copy medium 38 may be fabricated or treated to enhance the ability of the hard copy output engine to achieve variable gloss levels. This requires the user to select the hard copy output stock in order to influence gloss of the hard copy output 38. Examples include:

(i) A hard copy medium with increased pore volume to accommodate larger amounts of absorbed toner within the medium to facilitate the ability of the hard copy output device to selectively adjust surface film thickness in response to user preferences.

(ii) A hard copy medium treated with a temperature-sensitive wetting agent which selectively reduces toner surface tension during fusing in response to changes in fusing temperature thereby affecting gloss.

(iii) A hard copy medium coated with a polymer or other material having a gloss responsive to fusing temperature thereby enabling the hard copy output engine to selectively affect the gloss of printed and unprinted areas.

(iv) A hard copy medium coated with a polymer or other material which is soluble or miscible in toner during fusing and which selectively affects the gloss of the hard copy output after fusing in response to changes in fusing temperature, pressure or other process parameters which are adjusted according to user preferences.

(v) A hard copy medium coated with a polymer or other material which produces or liberates a gas during fusing, said gas causing an increase in the bulk or surface porosity of the image forming layer and causing a reduction in gloss of the hard copy output after fusing in response to changes in fusing temperature, pressure or other process parameters which are adjusted according to user preferences.

(vi) A hard copy medium coated with a polymer or other material which produces or liberates particles during fusing, said particles causing an increase in bulk or surface light scattering of the image forming layer and causing a reduction in gloss of the hard copy output after fusing in response to changes in fusing temperature, pressure or other process parameters which are adjusted according to user preferences.

(14) Additional Toner Cartridge(s) 32′, 32″ For Applying A “Gloss Enhancement”, “Gloss Modification” Or “Gloss Reduction” Agent. In color hard copy output engines 30 that ordinarily would employ four toner cartridges 32, one or more additional toner cartridges 32′ or 32″ may be employed to apply a gloss control agent to user-selectable portions of the hard copy output 38 product. Similarly, in monochromatic hard copy output engines 30 that ordinarily would employ a single toner cartridge, one or more additional toner cartridges 32′ or 32″ may be employed to apply a gloss control agent to user-selectable portions of the hard copy output 38 product. Additional toner cartridges 32′ or 32″ may be functionally similar to toner cartridges 32, and may include a photoconductor 34, for example, and may be associated with a laser 36 in the hard copy output engine 14.

When it is desired to reduce the number of laser scanning or exposure steps, the additional toner may be applied on a “per page” or “per image” basis, or on other forms of user-selectable portions of a page. When it is desired to achieve greater spatial resolution of the final gloss level distribution, “gloss modification” agent may be selectively applied to portions of the hard copy medium 38 in response to user input with a dot size and dot placement accuracy similar to that of toner applied by cartridges 32.

In one embodiment, gloss modification agent is formulated to selectively increase gloss. In another embodiment, gloss modification agent is formulated to selectively decrease gloss. Gloss modification agent may be pigmented or non-pigmented. Non-pigmented gloss modification agent may be applied to user-selectable portions of a page independently of the pigmented toners. Examples properties of the image forming layer which can be altered by gloss modification agent include:

(i) surface smoothness or micro-texture

(ii) surface porosity,

(iii) bulk porosity

(iv) the presence of particles or other inclusions which increase surface scattering or bulk light scattering, and

(v) the degree of fusion between adjacent toner particles.

The additional gloss toner cartridges 32′, 32″ may provide different gloss levels over various sub-portions of a page of hard copy output in response to user-selectable criteria. In one embodiment, a first and a second pigmented toner are applied in user-selectable proportions from separate toner cartridges. The first and second toners being formulated to provide substantially the same color at different levels of gloss. In response to user input, a proportion of toner of each formulation is selectively applied to produce a desired intermediate gloss level. For example, the first toner may provide a high gloss level and the second toner may provide a low gloss level.

The controller 20 can vary the gloss of hard copy output pages and selected areas within hard copy output pages using conventional techniques in response to user input. This allows multiple user-selectable gloss levels within a page, as well as page-to-page user-chosen variations in gloss.

The protection sought is not to be limited to the disclosed embodiments, which are given by way of example only, but instead is to be limited only by the scope of the appended claims.

What is claimed is:

1. A method of varying gloss in hard copy output from a hard copy output engine comprises:
providing a user with a user-adjustable control for varying hard copy output gloss; and
varying at least one processing parameter in producing the hard copy output in response to user adjustment of the user-adjustable control to provide a first user-selected gloss level over a first portion of a page of hard copy output.

2. The method of claim 1, further comprising:
sensing achieved gloss levels in hard copy output from the hard copy output engine; and
varying at least one processing parameter in producing the hard copy output in response to both the sensed achieved gloss level and user adjustment of the user-adjustable control.

3. The method of claim 1, wherein varying gloss in hard copy output includes varying gloss in a hard copy output engine that employs dry powdered material as for pigmentation of the hard copy medium.

4. The method of claim 1, wherein varying at least one parameter includes supplying a gloss modification agent to the hard copy medium during generation of the hard copy output.

5. The method of claim 1, wherein varying at least one parameter includes varying at least one parameter chosen from a list consisting of: Toner Mass Density; Media Gloss; Fusing Temperature; Fusing Pressure; Fusing Time; Cooling Rate; Nip Geometry; Auxiliary Heat; Number Of Passes; Use Of Multi-Gloss Toner; Special Hard Copy Media Or Treatments; and Using Additional Toner Cartridge(s) For Applying A “Gloss Enhancement”, “Gloss Modification” Or “Gloss Reduction” Overcoat.

6. The method of claim 1, wherein providing a user with a user-adjustable control includes providing a user with a user-adjustable control allowing page-to-page adjustment of achieved gloss levels.

7. The method of claim 1, wherein varying at least one parameter includes varying at least one parameter to provide the first user-selected gloss level over the first portion of the page of hard copy output and to provide a second user-selectable gloss level over a second portion of the page.

8. An apparatus for varying gloss in hard copy output from a hard copy output engine comprising:
a user interface facilitating user-adjustable variation of hard copy output gloss; and
a control mechanism configured to vary at least one processing parameter in producing the hard copy output in response to user adjustment of the user-adjustable control to provide a first user-selected gloss level over a first portion of a page of hard copy output.

9. The apparatus of claim 8, further comprising:
a sensor for sensing achieved gloss levels in hard copy output from the hard copy output engine; and
wherein the control mechanism configured to vary includes a control mechanism configured to vary at least one processing parameter in producing the hard copy output in response to both the sensed achieved gloss level and user adjustment of the user-adjustable control.

10. The apparatus of claim 8, wherein the hard copy output engine employs dry powdered material as for pigmentation of the hard copy medium

11. The apparatus of claim 8, wherein the control mechanism configured to vary includes a control mechanism configured to supply a gloss modification agent to the hard copy medium during generation of the hard copy output.

12. The apparatus of claim 8, wherein the control mechanism configured to vary includes a control mechanism configured to vary at least one parameter chosen from a list consisting of: Toner Mass Density; Media Gloss; Fusing Temperature; Fusing Pressure; Fusing Time; Cooling Rate; Nip Geometry; Auxiliary Heat; Number Of Passes; selecting Use Of Multi-Gloss Toner; selecting Special Hard Copy Media Or Treatments; and Using Additional Toner Cartridge(s) For Applying A “Gloss Enhancement”, “Gloss Modification” Or “Gloss Reduction” Overcoat.

13. The apparatus of claim 8, wherein the user interface includes a user interface configured to provide a user with a user-adjustable control allowing page-to-page adjustment of achieved gloss levels.

14. The apparatus of claim 8, wherein the user interface includes a user interface configured to provide the first user-selected gloss level over the first portion of the page of hard copy output and to provide a second user-selectable gloss level over a second portion of the page.

15. A computer implemented control system for a hard copy output engine, the system comprising processing circuitry coupled to the hard copy output engine and configured to:
provide a user interface configured to facilitate user-adjustable variation of hard copy output gloss; and
vary at least one processing parameter in producing the hard copy output in response to user adjustment of the user-adjustable control to provide a first user-selected gloss level over a first portion of a page of hard copy output.

16. The computer implemented control system of claim 15, wherein the processor configured to vary at least one processing parameter comprises a processor configured to
sense achieved gloss levels in hard copy output from the hard copy output engine; and
vary at least one processing parameter in producing the hard copy output in response to both the sensed achieved gloss level and user adjustment of the user-adjustable control.

17. The computer implemented control system of claim 15, wherein the processor configured to vary at least one processing parameter comprises a processor configured to supply a gloss modification agent to the hard copy medium during generation of the hard copy output.

18. The computer implemented control system of claim 15, wherein the processor configured to vary at least one processing parameter comprises a processor configured to vary at least one parameter chosen from a list consisting of: Toner Mass Density; Media Gloss; Fusing Temperature; Fusing Pressure; Fusing Time; Cooling Rate; Nip Geometry; Auxiliary Heat; Number Of Passes; selecting Use Of Multi-Gloss Toner; selecting Special Hard Copy Media Or Treatments; and Using Additional Toner Cartridge(s) For Applying A “Gloss Enhancement”, “Gloss Modification” Or “Gloss Reduction” Overcoat.

19. The computer implemented control system of claim 15, wherein the processor configured vary at least one processing parameter comprises a processor configured to provide a user with a user-adjustable control allowing page-to-page adjustment of achieved gloss levels.

20. The computer implemented control system of claim 15, wherein the processor configured to vary at least one processing parameter comprises a processor configured to provide the first user-selected gloss level over the first portion of the page of hard copy output and to provide a second user-selectable gloss level over a second portion of the page.
